(19) United States
(12) Patent Application Publication
(10) Pub. No.: US 2026/0223485 A1
(43) Pub. Date: Jul. 30, 2026

(54) PACKAGING STRUCTURE, IMAGING MODULE, AND CAMERA

(71) Applicant: ARASHI VISION INC., Shenzhen (CN)

(72) Inventors: Wenzhong ZHAO, Shenzhen (CN); Jin LU, Shenzhen (CN); Fei GAO, Shenzhen (CN); Li WANG, Shenzhen (CN); Xianyun TU, Shenzhen (CN)

(73) Assignee: ARASHI VISION INC., Shenzhen (CN)

(21) Appl. No.: 19/570,096

(22) Filed: Mar. 17, 2026

Related U.S. Application Data
(63) Continuation of application No. PCT/CN2023/119490, filed on Sep. 18, 2023.

(51) Int. Cl. H10F 77/60; H05K 1/02; H10F 77/00

(52) U.S. Cl. CPC H10F 77/60; H05K 1/0204; H10F 77/93; H05K 2201/10121

(57) ABSTRACT

In some aspects, a packaging structure is provided. The packaging structure may include a circuit board, a photosensitive chip, and a heat dissipation member. The photosensitive chip can be electrically connected to the circuit board. The photosensitive chip has a photosensitive surface and a heat dissipation surface that are disposed opposite each other. The heat dissipation member is at least partially in direct contact with the heat dissipation surface of the photosensitive chip.

### CROSS-REFERENCE TO RELATED APPLICATION

This application is a continuation of International Application No. PCT/CN2023/119490, filed on Sep. 18, 2023. The entire content of this application is hereby incorporated by reference in its entirety.

### BACKGROUND

The present disclosure relates to the technical field of cameras, and in particular, to a packaging structure, an imaging module, and a camera.

A camera mainly includes an Image Signal Processor (ISP), a sensor (e.g., an image sensor), and a lens. The sensor is typically packaged using Chips on Board (COB) technology, that is, the sensor is directly soldered onto a Printed Circuit Board (PCB). However, in the related art, the PCB is usually made of Flame Retardant 4 (FR4) material (e.g., glass fiber reinforced epoxy laminate), which has a relatively low thermal conductivity. The sensor generates a large amount of heat during operation, which leads to heat accumulation and temperature rise in the sensor. When the temperature of the sensor rises, it may trigger an over-temperature protection mechanism due to overheating, affecting the normal operation of the camera. In addition, it may also cause local high-temperature spots in the camera, negatively impacting the user experience.

### SUMMARY

The embodiments of the present disclosure provide a packaging structure, an imaging module, and a camera, which can at least improve the heat dissipation problem of the photosensitive chip.

In a first aspect, the embodiments of the present disclosure provide a packaging structure, which includes a circuit board, a photosensitive chip, and a heat dissipation member. The photosensitive chip is disposed on the circuit board and is electrically connected to the circuit board. The photosensitive chip includes a photosensitive surface and a heat dissipation surface that are disposed opposite each other. The heat dissipation member is at least partially in direct contact with the heat dissipation surface.

In some embodiments, the heat dissipation member is bonded to the circuit board, and the photosensitive chip is bonded to a side of the heat dissipation member away from the circuit board.

In some embodiments, the heat dissipation member has a connecting hole, and the connecting hole is used for the connecting wire to pass through.

In some embodiments, the circuit board has a through-hole, the heat dissipation member is bonded to the circuit board and covers at least a part of the through-hole, and the photosensitive chip is within the through-hole and bonded to a side of the heat dissipation member facing the circuit board.

In some embodiments, the circuit board has a through-hole, the heat dissipation member includes a sheet portion and a protruding portion, the sheet portion is bonded to the circuit board and covers at least a part of the through-hole, and the protruding portion is within the through-hole and connected to the sheet portion. The photosensitive chip is at least partially bonded to a side of the protruding portion away from the sheet portion.

In some embodiments, viewed along a depth direction of the through-hole, the protruding portion matches the through-hole.

In some embodiments, viewed along a depth direction of the through-hole, the through-hole matches the photosensitive chip.

In some embodiments, along a depth direction of the through-hole, a height of the protruding portion is equal to a depth of the through-hole.

In some embodiments, a part of the photosensitive chip is bonded to the protruding portion, and another part is bonded to a side of the circuit board away from the sheet portion.

In some embodiments, the heat dissipation member includes a sheet portion and an extending portion, the sheet portion is bonded to a surface of the circuit board, and the extending portion extends to another surface of the circuit board.

In some embodiments, the circuit board includes a first surface and a second surface that are disposed opposite each other, the sheet portion is bonded to one of the first surface and the second surface, and the extending portion extends to the other of the first surface and the second surface.

In some embodiments, the heat dissipation member includes a first layer and a second layer, the first layer is bonded to a surface of the circuit board, and the second layer is bonded to a side of the first layer away from the circuit board. The first layer is used to conduct heat of the photosensitive chip, and the second layer is used to conduct heat in the first layer.

In some embodiments, the heat dissipation member includes an extending portion. The extending portion is formed by extending from the second layer. The extending portion extends to another surface of the circuit board, and a bending performance of the second layer is better than a bending performance of the first layer.

In some embodiments, the circuit board has a through-hole, the photosensitive chip is disposed in the through-hole, and the heat dissipation member is bonded to the heat dissipation surface.

In some embodiments, the heat dissipation surface is provided with a thermally conductive adhesive.

In a second aspect, the embodiments of the present disclosure further provide an imaging module, which includes a lens holder, a lens, and any one of the above packaging structures. The lens holder is provided with a light-passing hole penetrating two ends. The lens is disposed on one end of the lens holder, and the lens is used to transmit light into the light-passing hole. The packaging structure is disposed on the other end of the lens holder, and enables the photosensitive chip to receive light transmitted by the lens.

In some embodiments, the imaging module further includes an optical filter, and the optical filter is at least partially disposed between the lens and the photosensitive chip.

In some embodiments, the optical filter covers the packaging structure, and encloses with the packaging structure to form a sealed cavity, and the photosensitive chip is located within the sealed cavity.

In a third aspect, the embodiments of the present disclosure further provide a camera, which includes any one of the above packaging structures or imaging modules.

Unlike the related art, the packaging structure, imaging module, and camera provided by the embodiments of the present disclosure, by providing a heat dissipation member that is fitted with the heat dissipation surface of the photosensitive chip, can accelerate the heat dissipation efficiency of the photosensitive chip and improve the heat dissipation problem of the photosensitive chip.

The above description is only a summary of the technical solutions of the present disclosure. In order to better understand the technical means of the present disclosure, the content can be implemented according to the description, and in order to make the above and other objectives, features, and advantages of the present disclosure more obvious and understandable, specific embodiments of the present disclosure are listed below.

### BRIEF DESCRIPTION OF DRAWINGS

One or more embodiments are illustratively described by the corresponding drawings. These illustrative descriptions do not constitute limitations on the embodiments. Elements with the same reference numerals in the drawings represent similar elements. Unless otherwise specified, the drawings do not constitute proportional limitations.

FIG. 1 is a front view of a conventional packaging structure.

FIG. 2 is a front view of a first packaging structure according to some embodiments of the present disclosure.

FIG. 3 is a top view of a first packaging structure according to some embodiments of the present disclosure.

FIG. 4 is a sectional view of a second packaging structure according to some embodiments of the present disclosure.

FIG. 5 is a top view of a second packaging structure according to some embodiments of the present disclosure.

FIG. 6 is a top view of a second packaging structure having a configuration different from FIG. 5 according to some embodiments of the present disclosure.

FIG. 7 is a sectional view of a third packaging structure according to some embodiments of the present disclosure.

FIG. 8 is a top view of a third packaging structure according to some embodiments of the present disclosure.

FIG. 9 is a top view of a third packaging structure having a configuration different from FIG. 8 according to some embodiments of the present disclosure;

FIG. 10 is a front view of a fourth packaging structure according to some embodiments of the present disclosure.

FIG. 11 is a front view of a fourth packaging structure according to some embodiments of the present disclosure.

FIG. 12 is a sectional view of a fourth packaging structure according to some embodiments of the present disclosure.

FIG. 13 is a front view of a fifth packaging structure according to some embodiments of the present disclosure.

FIG. 14 is a front view of a fifth packaging structure according to some embodiments of the present disclosure.

FIG. 15 is a sectional view of a sixth packaging structure according to some embodiments of the present disclosure.

FIG. 16 is a top view of a sixth packaging structure according to some embodiments of the present disclosure.

FIG. 17 is a front view of a seventh packaging structure according to some embodiments of the present disclosure.

FIG. 18 is a schematic structural diagram of an imaging module according to some embodiments of the present disclosure.

FIG. 19 is a partial sectional perspective view of an imaging module according to some embodiments of the present disclosure.

FIG. 20 is a partial sectional perspective view of another imaging module according some embodiments of the present disclosure.

FIG. 21 is a schematic structural diagram of a camera according to some embodiments of the present disclosure.

The present disclosure will be described with reference to the accompanying drawings.

### DETAILED DESCRIPTION

The following will describe the technical solutions in the embodiments of the present disclosure in conjunction with the accompanying drawings in the embodiments of the present disclosure. Obviously, the described embodiments are only a part of the embodiments of the present disclosure and not all embodiments. The description of at least one exemplary embodiment below is merely illustrative and in no way should be construed as any limitation on the present disclosure and its application or use.

In the description of the present disclosure, it should be noted that positional words such as “front, rear, upper, lower, left, right,” “horizontal, vertical, perpendicular, level,” and “top, bottom” generally refer to the positional or spatial relationships shown in the drawings, and are only for the convenience of describing the present disclosure and simplifying the description. Unless otherwise specified, these positional words do not indicate or imply that the referenced device or element must have a particular orientation or be constructed and operated in a particular orientation, and thus should not be construed as limiting the scope of protection of the present disclosure. The positional terms “inner” and “outer” refer to the inside and outside relative to the outline of each component itself.

In the description of the present disclosure, it should be noted that the use of terms such as “first,” “second,” etc., to define components is only for the convenience of distinguishing the corresponding components, and unless otherwise stated, the above words do not have any special meaning and thus should not be construed as limiting the scope of protection of the present disclosure.

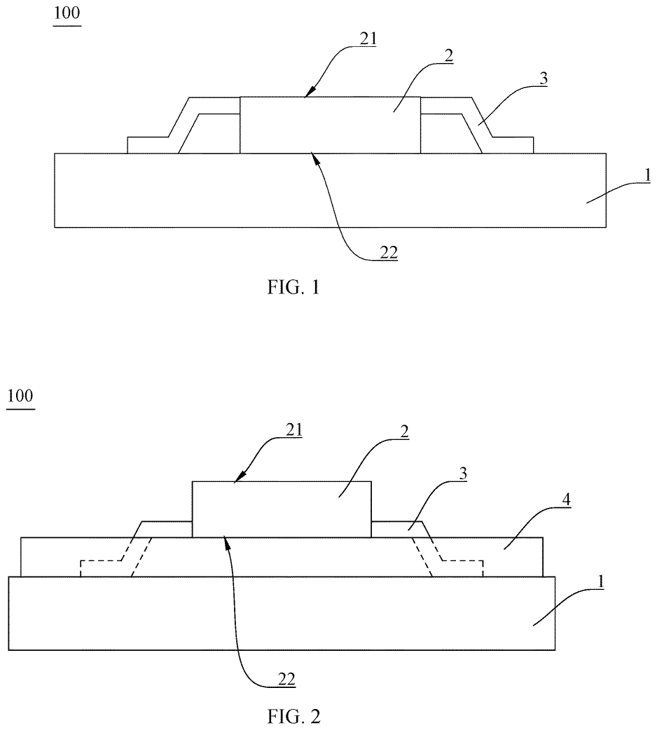

FIG. 1 shows a packaging structure 100, which is used for imaging devices, for example, for cameras. As shown in FIG. 1, the packaging structure 100 includes a circuit board 1 and a photosensitive chip 2. The photosensitive chip 2 is disposed on the circuit board 1 and is electrically connected to the circuit board 1 via a connecting wire 3. The photosensitive chip 2 includes a photosensitive surface 21. A Complementary Metal-Oxide Semiconductor (CMOS) or a Charge Coupled Device (CCD) is provided on the photosensitive surface 21, which is configured to convert optical signals into electrical signals, and then the electrical signals are processed by the processor of the camera to form an image.

The shape of the circuit board 1 and the shape of the photosensitive chip 2 are not limited, as long as the photosensitive chip 2 can be disposed on the circuit board 1 and the photosensitive surface 21 is not blocked. The manner in which the photosensitive chip 2 is connected to the circuit board 1 via the connecting wire 3 is not limited, as long as the circuit board 1 and the photosensitive chip 2 can be connected.

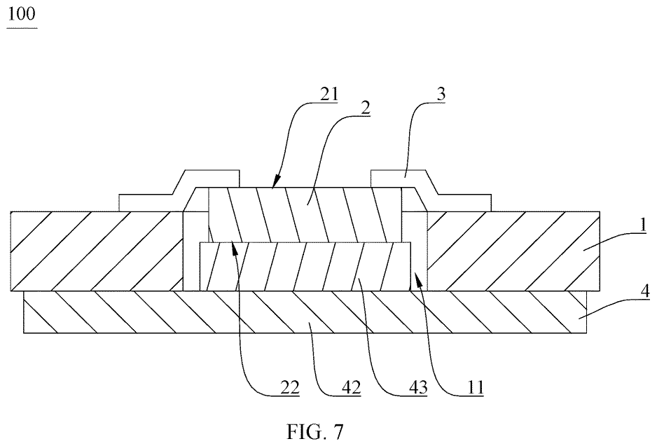

It should be noted that, in the related art, as shown in FIG. 1, the photosensitive chip 2 is usually directly bonded to the circuit board 1, and the circuit board 1 is usually made of FR4 material, which has a low thermal conductivity and is not conducive to the heat dissipation of the photosensitive chip 2. To address this problem and others, as shown in FIG. 2, FIG. 4, FIG. 7, and FIG. 15, a packaging structure 100 can be provided. In accordance with the present disclosure, the packaging structure 100 can be provided with a heat dissipation member 4. The heat dissipation member 4 is at least partially fitted with a surface of the photosensitive chip 2, so as to transfer heat to the heat dissipation member 4, thereby accelerating the heat dissipation efficiency of the photosensitive chip 2 and improving the heat dissipation problem of the photosensitive chip 2.

In the present disclosure, the description “at least partially fitted” (used to describe the relation between the heat dissipation member 4 and the photosensitive chip 2) means that a portion of the surface of the heat dissipation member 4 is in direct thermal contact with the photosensitive chip 2, or the heat dissipation member 4 is in direct thermal contact with a portion of the surface of the photosensitive chip 2. This partial fitting allows heat generated by the photosensitive chip 2 to be effectively transferred to the heat dissipation member 4. It can be understood that the thermal conductivity of the heat dissipation member 4 is greater than that of the circuit board 1.

For ease of description, in the corresponding figures, the circuit board 1, the photosensitive chip 2, and the heat dissipation member 4 are illustrated as rectangular boxes by way of example. The surface of each of these components facing the same direction as the photosensitive surface 21 is defined as the front surface, the surface opposite to the photosensitive surface 21 is defined as the back surface, and the other surfaces are defined as side surfaces. It can be understood that the circuit board 1, the photosensitive chip 2, and the heat dissipation member 4 may also be of other shapes, such as block-shaped, strip-shaped, etc.

It can be understood that the back surface of the photosensitive chip 2 has a larger heat-conducting area compared to the side surfaces, and thus has a better heat dissipation effect. Therefore, in the context of the present disclosure, the back surface of the photosensitive chip 2 is referred to as a heat dissipation surface 22. In other words, the photosensitive chip 2 includes the photosensitive surface 21 and the heat dissipation surface 22 disposed opposite each other. Take the example where the heat dissipation surface 22 is fitted with the heat dissipation member 4. In this example, the heat dissipation member 4 is at least partially fitted with the heat dissipation surface 22, so as to further improve the heat dissipation effect of the photosensitive chip 2.

In the following descriptions, the exemplary structures of the circuit board 1 and the heat dissipation member 4, as well as the exemplary fitting relationships among the circuit board 1, the photosensitive chip 2, and the heat dissipation member 4 are mainly described.

As shown in FIG. 2, the heat dissipation member 4 is bonded to a surface of the circuit board 1, and the photosensitive chip 2 is bonded to a side of the heat dissipation member 4 away from the circuit board 1. For example, the heat dissipation member 4 can be bonded to the front surface of the circuit board 1, and the photosensitive chip 2 is bonded to the front surface of the heat dissipation member 4, so that the heat dissipation member 4 can quickly transfer the heat of the photosensitive chip 2. Accordingly, the heat dissipation problem of the photosensitive chip 2 can be improved.

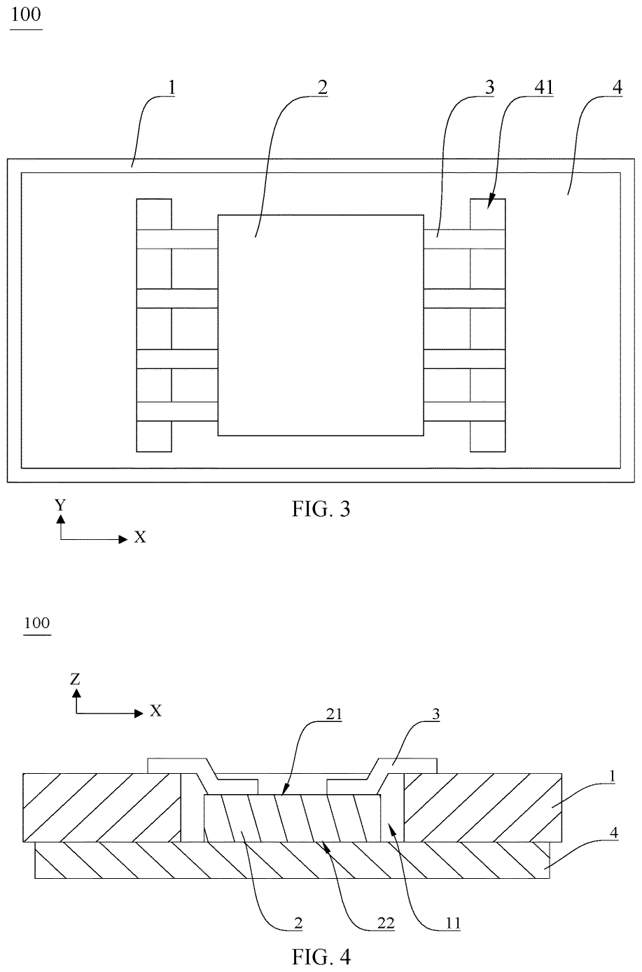

In this embodiment, since the heat dissipation member 4 spaces the photosensitive chip 2 from the circuit board 1, it may hinder the electrical connection between the photosensitive chip 2 and the circuit board 1 via the connecting wire 3. To address this issue, as shown in FIG. 3, the heat dissipation member 4 may be provided with a connecting hole 41, which is configured for the connecting wire 3 to pass through, so that the connecting wire 3 between the photosensitive chip 2 and the circuit board 1 does not need to be extended to bypass the heat dissipation member 4, and no additional manufacturing cost is incurred. In some embodiments, the connecting hole 41 may be elongated (e.g., along the Y-direction in FIG. 3) to allow multiple connecting wires 3 to pass through.

FIG. 4 shows a second packaging structure 100 according to some embodiments of the present disclosure. As shown in FIG. 4, the circuit board 1 is provided with a through-hole 11, the heat dissipation member 4 is bonded to a surface of the circuit board 1 and covers at least a part of the through-hole 11, and the photosensitive chip 2 is within the through-hole 11 and bonded to a side of the heat dissipation member 4 facing the circuit board 1. For example, the heat dissipation member 4 is bonded to the back surface of the circuit board 1 and completely covers the through-hole 11, and the photosensitive chip 2 is bonded to the heat dissipation member 4, with the heat dissipation surface 22 of the photosensitive chip 2 located within the through-hole 11. The height by which the photosensitive chip 2 protrudes from the circuit board 1 is small, thus shortening the distance between the lens 202 and the circuit board 1 and thereby reducing the size of the camera.

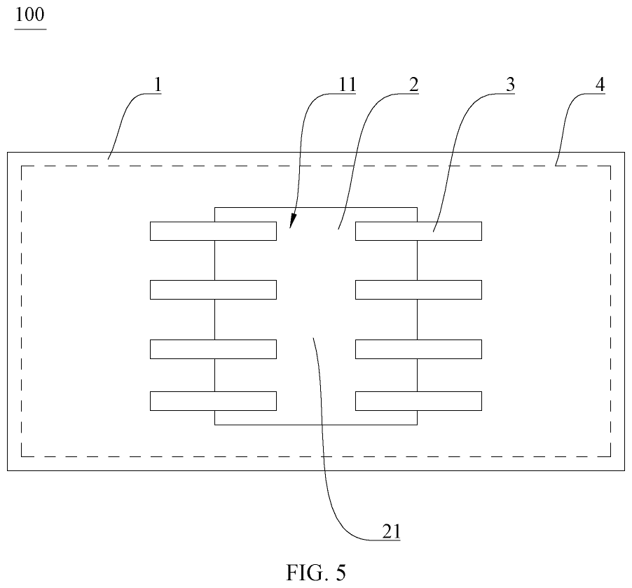

In the embodiment, viewed along the depth direction (e.g., the Z-direction in FIG. of the through-hole 11, the through-hole 11 may match or correspond to the photosensitive chip 2. For example, as shown in FIG. 5, viewed along the depth direction of the through-hole 11, the shape and size of the through-hole 11 correspond to those of the photosensitive chip 2. In some examples, the shape and size of the through-hole 11 can be identical to those of the photosensitive chip 2 to enable the photosensitive chip 2 to contact the inner wall of the through-hole 11. Accordingly, the photosensitive chip 2 can be embedded in the through-hole 11, enabling the through-hole 11 to serve to fix the photosensitive chip 2. Further, the photosensitive chip 2 contacts the inner wall of the through-hole 11, which can transfer heat to the circuit board 1 and further improve the heat dissipation effect of the photosensitive chip 2.

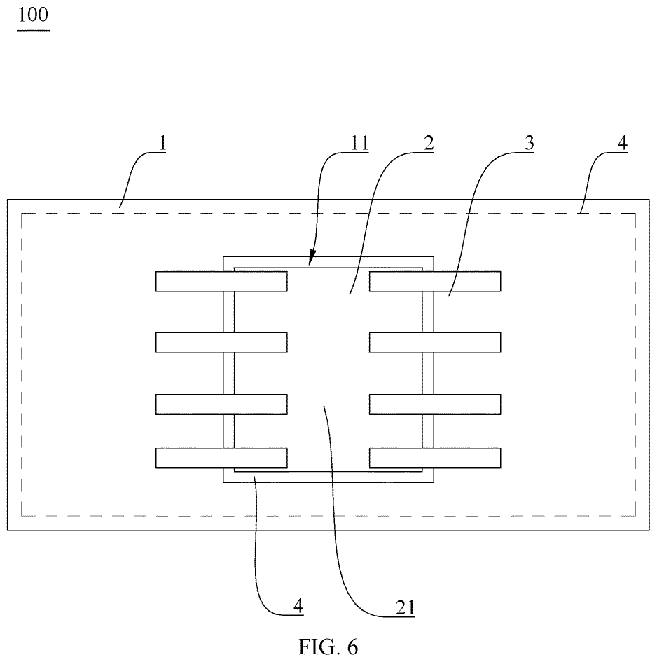

In other examples, as shown in FIG. 6, viewed along the depth direction of the through-hole 11, the shape of the through-hole 11 is the same as that of the photosensitive chip 2, but the size of the through-hole 11 is slightly larger than that of the photosensitive chip 2. Consequently, there is a certain gap between the photosensitive chip 2 and the inner wall of the through-hole 11, which facilitates the installation of the photosensitive chip 2 in the through-hole 11.

In view of FIGS. 5 and 6, the through-hole 11 may match or slightly exceed the dimensions of the photosensitive chip 2 to either secure the photosensitive chip 2 via tight fit or ease installation with clearance.

FIG. 7 shows a sectional view of a third packaging structure according to some embodiments of the present disclosure. As shown in FIG. 7, the circuit board 1 is provided with a through-hole 11, the heat dissipation member 4 includes a sheet portion 42 and a protruding portion 43. In some examples, the sheet portion 42 can be bonded to a surface of the circuit board 1 and cover at least a portion of the through-hole 11, and the protruding portion 43 can be arranged within the through-hole 11 and connected to the sheet portion 42. The photosensitive chip 2 is at least partially bonded to a side of the protruding portion 43 away from the sheet portion 42. For example, the sheet portion 42 is bonded to the back surface of the circuit board 1 and completely covers the through-hole 11, the protruding portion 43 is bonded to the front surface of the sheet portion 42, and the photosensitive chip 2 is bonded to the front surface of the protruding portion 43. The heat dissipation member 4 includes the protruding portion 43, and the photosensitive chip 2 is disposed on the protruding portion 43. This can increase the height by which the photosensitive chip 2 protrudes from the circuit board 1, and address the problem that the edge of the through hole 11 blocks light.

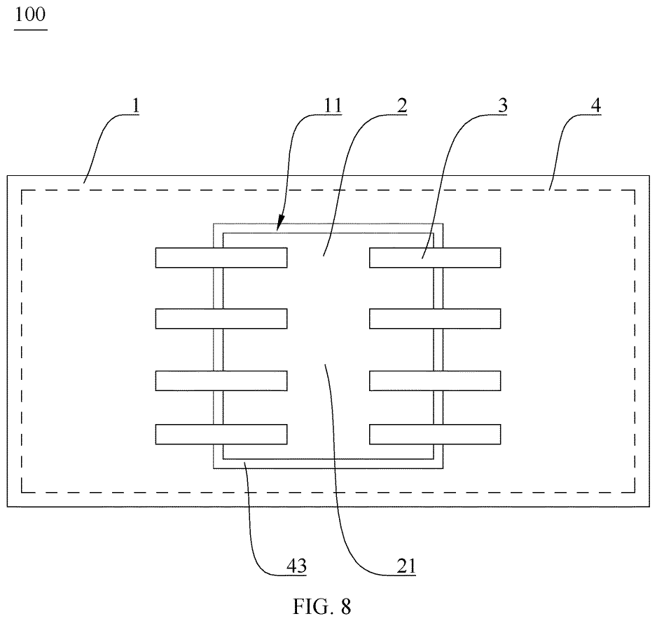

In the embodiment, as shown in FIG. 8, the protruding portion 43 may match the through-hole 11. For example, viewed along the depth direction of the through-hole 11, the shape and size of the protruding portion 43 are the same as those of the through-hole 11, so that when the protruding portion 43 is inserted into the through-hole 11, the through-hole 11 can serve to limit the position of the protruding portion 43 and the heat dissipation member 4, facilitating the positioning of the heat dissipation member 4 when it is installed on the circuit board 1. There may be friction between the inner wall of the through-hole 11 and the protruding portion 43, which can enhance the connection strength between the heat dissipation member 4 and the circuit board 1.

In some embodiments, along the depth direction of the through-hole 11, the height of the protruding portion 43 is equal to the depth of the through-hole 11, and the photosensitive chip 2 is at least partially bonded to a side of the protruding portion 43 away from the sheet portion 42. Since the height of the protruding portion 43 is equal to the depth of the through-hole 11, the height by which the photosensitive chip 2 protrudes from the circuit board 1 is the same as that of the packaging structure 100 shown in FIG. 1, so there is no need to change the distance between a lens 202 (e.g., in FIG. 18) and the circuit board 1, and other components of the camera with the packaging structure 100 in FIG. 1 can be directly used, which is conducive to reducing production costs.

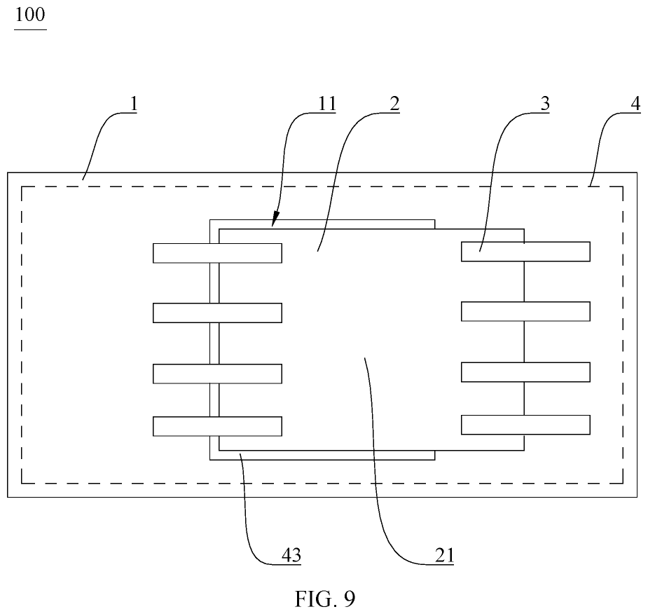

In the embodiment, as shown in FIG. 9, when the height of the protruding portion 43 is equal to the depth of the through-hole 11, a portion of the photosensitive chip 2 can be bonded to the protruding portion 43, and another portion of the photosensitive chip 2 can be bonded to a side of the circuit board 1 away from the sheet portion 42. For example, a portion of the photosensitive chip 2 is bonded to the front surface of the protruding portion 43, and another portion is bonded to the front surface of the circuit board 1.

In some embodiments, along the extension direction of the through-hole 11, the height of the protruding portion 43 may also be greater than or less than the depth of the through-hole 11. This can raise or lower the height by which the photosensitive chip 2 protrudes from the circuit board 1. When the distance between the lens 202 and the photosensitive chip 2 needs to be adjusted, only the height of the protruding portion 43 needs to be adjusted, and there is no need to change other components of the camera, which is conducive to reducing production costs. When the height of the protruding portion 43 is less than the depth of the through-hole 11, the photosensitive chip 2 is partially or completely located within the through-hole 11, and the through-hole 11 can serve to limit the position of the photosensitive chip 2.

In the embodiment, when the height of the protruding portion 43 is equal to or greater than the depth of the through-hole 11, viewed along the depth direction of the through-hole 11, the through-hole 11 and the photosensitive chip 2 may match. For example, viewed along the depth direction of the through-hole 11, the shape and size of the through-hole 11 are the same as those of the photosensitive chip 2, so that the protruding portion 43 can completely cover the heat dissipation surface 22 of the photosensitive chip 2. Consequently, the heat dissipation member 4 and the photosensitive chip 2 have the maximum contact area, which is conducive to improving the heat dissipation effect. The through-hole 11 and the photosensitive chip 2 may also not match, as long as the protruding portion 43 can pass through the through-hole 11.

In the embodiment, when the height of the protruding portion 43 is less than the depth of the through-hole 11, the through-hole 11 needs to match the photosensitive chip 2, so that the photosensitive chip 2 can be installed in the through-hole 11. For example, as shown in FIG. 5, viewed along the depth direction of the through-hole 11, the shape and size of the through-hole 11 are the same as those of the photosensitive chip 2, so that the photosensitive chip 2 can be partially or completely embedded in the through-hole 11. It enables the through-hole 11 to serve to fix the photosensitive chip 2, and the photosensitive chip 2 contacts the inner wall of the through-hole 11, which can transfer heat to the circuit board 1 and further improve the heat dissipation effect of the photosensitive chip 2. For example, as shown in FIG. 6, viewed along the depth direction of the through-hole 11, the shape of the through-hole 11 is the same as that of the photosensitive chip 2, but the size of the through-hole 11 is slightly larger than that of the photosensitive chip 2. so that there is a certain gap between the photosensitive chip 2 and the inner wall of the through-hole 11, which facilitates the installation of the photosensitive chip 2 in the through-hole 11.

In some embodiments, the protruding portion 43 is formed by extending from the middle of the sheet portion 42, so that there is no need to weld or bond between the protruding portion 43 and the sheet portion 42, which simplifies the processing technology of the heat dissipation member 4 and facilitates the manufacture of the heat dissipation member 4.

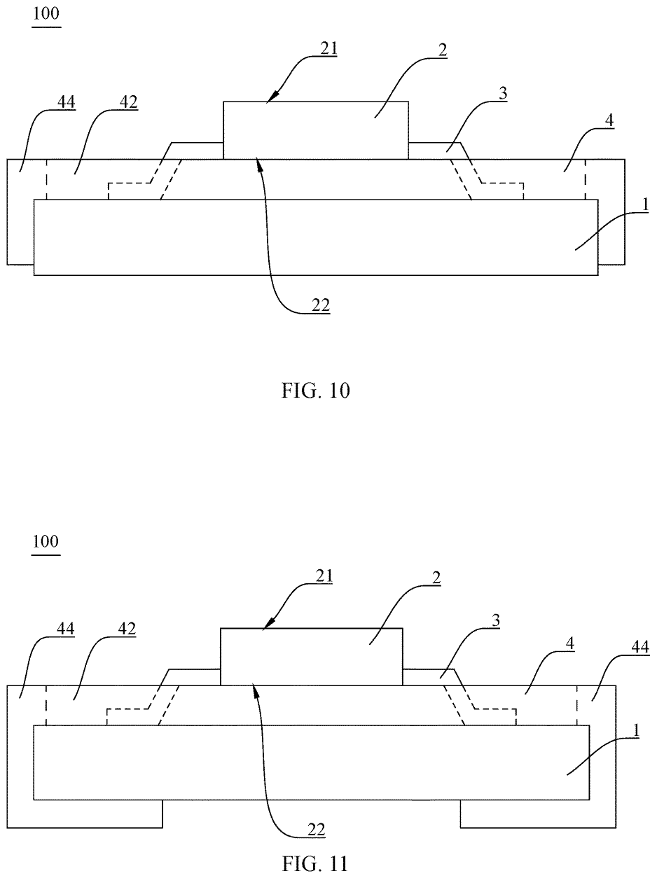

FIG. 10 shows a front view of a fourth packaging structure according to some embodiments of the present disclosure. As shown in FIG. 10, the heat dissipation member 4 includes a sheet portion 42 and an extending portion 44, the sheet portion 42 is bonded to a surface of the circuit board 1, and the extending portion 44 extends to another surface of the circuit board 1. For example, the sheet portion 42 is bonded to the front surface of the circuit board 1, and the extending portion 44 extends to the side surface of the circuit board 1 or extends to the back surface of the circuit board 1, so that the surface area of the heat dissipation member 4 can be increased, the heat dissipation efficiency of the heat dissipation member 4 can be improved, and the heat dissipation efficiency of the photosensitive chip 2 can be indirectly improved.

Further, the circuit board 1 includes a first surface and a second surface disposed opposite each other, the sheet portion 42 is bonded to one of the first surface and the second surface (i.e., either the first surface or the second surface), and the extending portion 44 extends to the other of the first surface and the second surface. For example, as shown in FIG. 11, the sheet portion 42 is bonded to the front surface of the circuit board 1, and the extending portion 44 extends to the back surface of the circuit board 1. Since the front and back surfaces of the circuit board 1 have a large area, extending the extending portion 44 to the back surface of the circuit board 1 can fully increase the surface area of the heat dissipation member 4 and improve the heat dissipation efficiency. The extending portion 44 may also extend to the housing of the camera to transfer heat to the housing of the camera and improve the heat dissipation efficiency.

In some embodiments, as shown in FIG. 11, the number of extending portions 44 is plural, and the plural extending portions 44 are arranged at intervals. Thus, the extending portions 44 can wrap the circuit board 1 from multiple directions, further increasing the surface area of the heat dissipation member 4 and improving the heat dissipation efficiency.

In some embodiments, the extending portion 44 is formed by extending from the edge of the sheet portion 42, so that there is no need to weld or bond between the extending portion 44 and the sheet portion 42, which simplifies the processing technology of the heat dissipation member 4 and facilitates the manufacture of the heat dissipation member 4.

In some examples, the material of the heat dissipation member 4 is metal, for example, copper, aluminum, stainless steel, copper alloy, aluminum alloy, magnesium alloy, etc., which have excellent thermal conductivity.

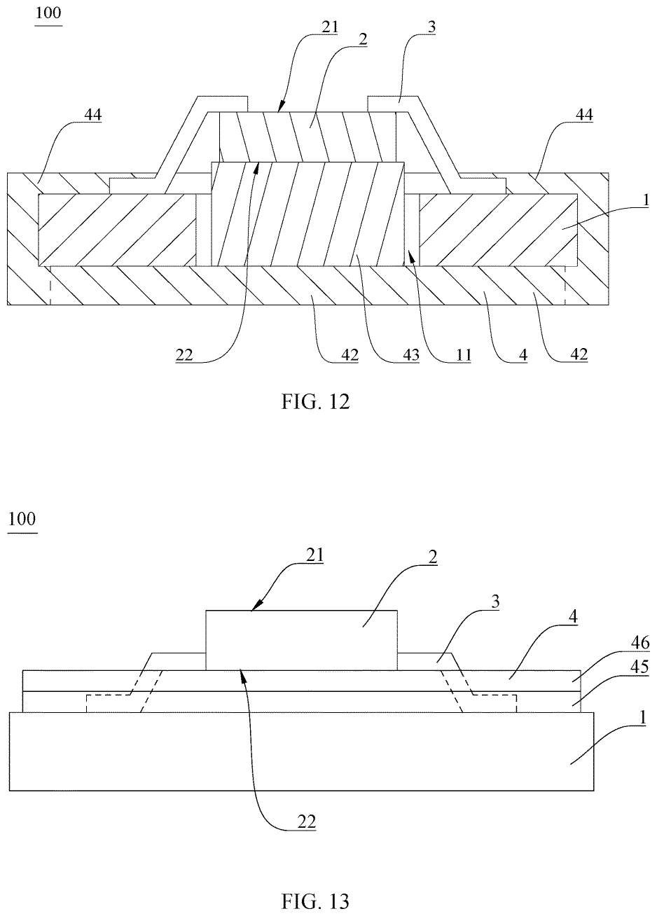

Further, in some examples, as shown in FIG. 12, the sheet portion 42 is bonded to the back surface of the circuit board 1, and the extending portion 44 extends to the front surface of the circuit board 1. The circuit board 1 is provided with a through-hole 11. The heat dissipation member 4 further includes a protruding portion 43, the protruding portion 43 is within the through-hole 11 and connected to the sheet portion 42, and the photosensitive chip 2 is bonded to the front surface of the protruding portion 43. Along the extension direction of the through-hole 11, the height of the protruding portion 43 is greater than the depth of the through-hole 11, and the portion of the protruding portion 43 protruding from the through-hole 11 is connected to the extending portion 44. Thus, the protruding portion 43 can directly transfer heat to the extending portion 44, improving the heat dissipation efficiency of the protruding portion 43 and further improving the heat dissipation efficiency of the photosensitive chip 2.

FIG. 13 shows a front view of a fifth packaging structure according to some embodiments of the present disclosure. As shown in FIG. 13, the heat dissipation member 4 includes a first layer 45 and a second layer 46, the first layer 45 is bonded to the surface of the circuit board 1, and the second layer 46 is bonded to a side of the first layer 45 away from the circuit board 1. The first layer 45 is used to conduct heat of the photosensitive chip 2 and may be a heat-conducting layer. The second layer 46 is used to conduct heat in the first layer 45, so that the heat in the first layer 45 can be transferred out, and the temperature difference in the first layer 45 can be reduced. The second layer 46 may be a heat-spreading layer. For example, the first layer 45 is bonded to the front surface of the circuit board 1, the second layer 46 is bonded to the front surface of the first layer 45, the first layer 45 is a metal plate, and the second layer 46 is a heat-spreading plate (e.g., a heat sink).

It should be noted that the heat-spreading plate may be a type of heat pipe. By bonding the heat-spreading plate to the metal plate, the efficiency of heat conduction on the metal plate can be improved, so that the temperature difference on the metal plate is reduced, the temperature at the bonding position between the metal plate and the photosensitive chip 2 is reduced, and the temperature difference between the photosensitive chip 2 and the metal plate is increased, which is conducive to improving the heat conduction efficiency from the photosensitive chip 2 to the metal plate.

It can be understood that the second layer 46 may be another heat-spreading layer with a heat-spreading function, and the first layer 45 may also be another heat-conducting layer with a heat-conducting function. Therefore, in this embodiment, by providing the heat dissipation member 4 as the first layer 45 and the second layer 46 bonded to each other, the heat dissipation efficiency of the heat dissipation member 4 for the photosensitive chip 2 can be improved.

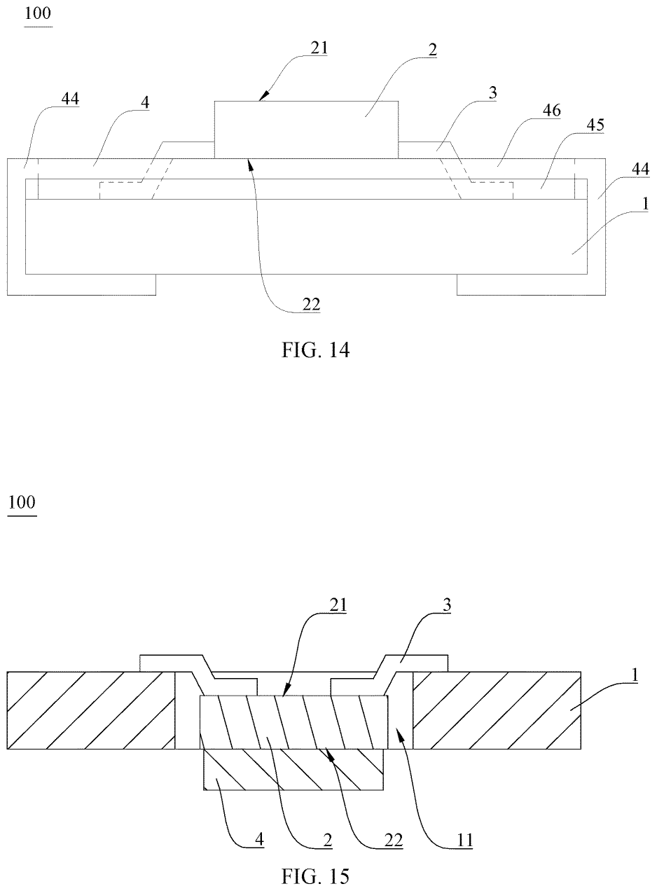

In this embodiment, as shown in FIG. 14, the heat dissipation member 4 may further include an extending portion 44. The extending portion 44 is formed by extending from the second layer 46, and the extending portion 44 extends to another surface of the circuit board 1. The difference between the extending portion 44 in this embodiment and the extending portion 44 in Embodiment 4 is that the extending portion 44 in this embodiment is formed by extending from the second layer 46, while the extending portion 44 in, for example, FIG. 10 or FIG. 11 is formed by extending from the sheet portion 42. Further, the bending performance of the second layer 46 is better than that of the first layer 45, so that the second layer 46 is easier to bend than the first layer 45. Hence, the extending portion 44 is easier to bend. The bending performance can also be reflected by ductility, and good ductility means good bending performance.

In this embodiment, the material of the first layer 45 can be metal, for example, copper, aluminum, stainless steel, copper alloy, aluminum alloy, magnesium alloy, etc., which have excellent thermal conductivity. The material of the second layer 46 can be graphite, graphene, heat pipe, Vapor Chamber (VC) heat-spreading plate, heat storage material, annular liquid cooling plate, etc., which have excellent heat-spreading performance (e.g., the heat-dissipation efficiency). In the embodiment, when the material of the second layer 46 can be a material with bendable performance such as graphite, graphene, heat storage material, etc., the extending portion 44 can extend and/or bend from one surface of the circuit board 1 to another surface of the circuit board 1. Preferably, the second layer 46 is made of graphene, which has excellent bending resistance and excellent heat-spreading performance.

FIG. 15 shows a sectional view of a sixth packaging structure according to some embodiments of the present disclosure. As shown in FIG. 15, the circuit board 1 is provided with a through-hole 11, the photosensitive chip 2 is disposed in the through-hole 11, and the heat dissipation member 4 is bonded to the heat dissipation surface 22. For example, the photosensitive chip 2 is embedded in the through-hole 11, the heat dissipation member 4 is bonded to the heat dissipation surface 22, and the other surface of the heat dissipation member 4 is used to contact the camera, so as to transfer heat to a portion of the camera other than the packaging structure 100, thereby achieving heat dissipation for the photosensitive chip 2. In this embodiment, the heat dissipation member 4 may be a Thermal Interface Material (TIM), such as a thermal gel, and no other glue is needed to bond the TIM material to the heat dissipation surface 22.

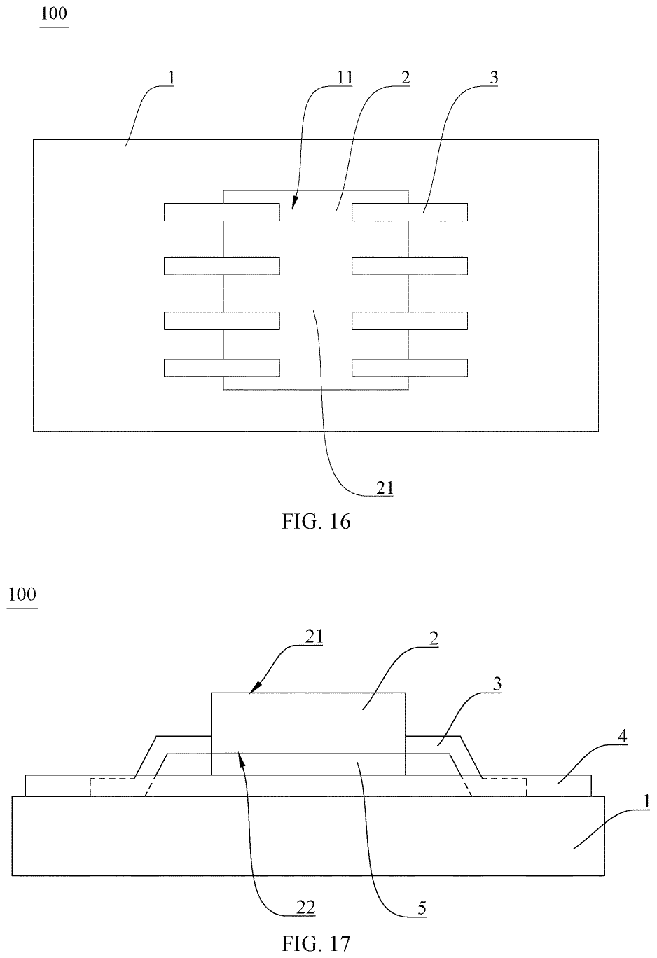

In the embodiment, as shown in FIG. 16, viewed along the depth direction of the through-hole 11, the through-hole 11 may match the photosensitive chip 2. For example, viewed along the depth direction of the through-hole 11, the shape and size of the through-hole 11 are the same as those of the photosensitive chip 2, so that the photosensitive chip 2 can be embedded in the through-hole 11, enabling the through-hole 11 to serve to fix the photosensitive chip 2, and the photosensitive chip 2 contacts the inner wall of the through-hole 11, which can transfer heat to the circuit board 1 and further improve the heat dissipation effect of the photosensitive chip 2.

FIG. 17 shows a front view of a seventh packaging structure according to some embodiments of the present disclosure. As shown in FIG. 17, the heat dissipation surface 22 is provided with a thermally conductive adhesive 5. By providing the thermally conductive adhesive 5 on the heat dissipation surface 22, the heat dissipation efficiency from the photosensitive chip 2 to the heat dissipation member 4 can be improved, and the thermally conductive adhesive 5 can also bond the photosensitive chip 2 to the heat dissipation member 4. The thermally conductive adhesive 5 may be a silver adhesive.

Based on the same technical concept, some aspects of the present disclosure further provide an imaging module 200. As shown in FIG. 18, the imaging module 200 includes a lens holder 201, a lens 202, and the above packaging structure 100. The lens holder 201 is provided with a light-passing hole 2011 penetrating two ends. The lens 202 is disposed on one end of the lens holder 201, and the lens 202 is used to transmit light into the light-passing hole 2011. The packaging structure 100 is disposed on the other end of the lens holder 201, and enables the photosensitive chip 2 to receive light transmitted by the lens 202. The imaging module 200 has the structural features and beneficial effects of the packaging structure 100, which will not be repeated here.

The structures of the lens holder 201 and the lens 202 are not limited here, as long as the lens holder 201 can fix the relative positions between the lens 202 and the packaging structure 100, and the lens 202 can focus light onto the photosensitive surface 21 of the photosensitive chip 2. The lens 202 may be a straight tube lens or a folded fisheye lens. The lens holder 201 may be made of metal or plastic. The connection between the lens 202 and the lens group may be adhesive or snap-fit.

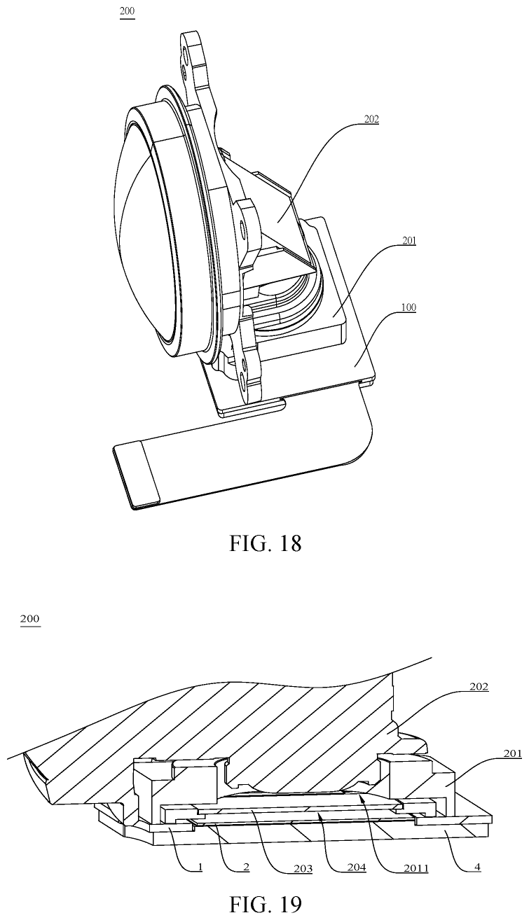

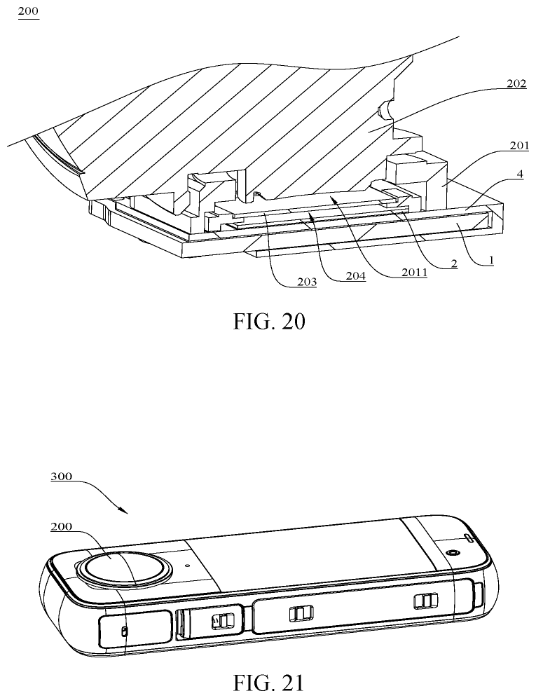

Further, as shown in FIG. 19 and FIG. 20, the imaging module 200 further includes an optical filter 203, and the optical filter 203 is at least partially disposed between the lens 202 and the photosensitive chip 2. The optical filter 203 can filter out light of specific wavelengths to reduce the influence of stray light on imaging. In some embodiments, the optical filter 203 is bonded to the packaging structure 100 by adhesive. In some embodiments, the optical filter 203 is an infrared filter, which is used to absorb infrared light to reduce illumination and filter out light reflected onto the lens 202, thereby improving imaging clarity.

Further, as shown in FIG. 19 and FIG. 20, the optical filter 203 covers the packaging structure 100, and encloses the packaging structure 100 to form a sealed cavity 204, and the photosensitive chip 2 is located within the sealed cavity 204. By sealing the photosensitive chip 2 in the sealed cavity 204, the photosensitive chip 2 is protected from external moisture and contaminants, thereby providing sealing protection for the photosensitive chip 2.

In some embodiments, as shown in FIG. 19, when the heat dissipation member 4 is disposed on the back surface of the circuit board 1, the lens holder 201 is connected to the circuit board 1. As shown in FIG. 20, when the heat dissipation member 4 is disposed on the front surface of the circuit board 1, the lens holder 201 is connected to the heat dissipation member 4.

Based on the same technical concept, as shown in FIG. 21, some aspects of the present disclosure further provide a camera 300, which includes the above packaging structure 100 or the imaging module 200. The camera 300 has the structural features and beneficial effects of the imaging module 200 or the packaging structure 100, which will not be repeated here.

The packaging structure 100, imaging module 200, and camera of the embodiments of the present disclosure, by providing a heat dissipation member 4 that is fitted with the heat dissipation surface 22 of the photosensitive chip 2, can accelerate the heat dissipation efficiency of the photosensitive chip 2 and improve the heat dissipation problem of the photosensitive chip 2. The heat dissipation member 4 includes a protruding portion 43 disposed in the through-hole 11 of the circuit board 1, which can change the height by which the photosensitive chip 2 protrudes from the circuit board 1 to meet different requirements. The heat dissipation member 4 includes an extending portion 44, which can increase the surface area of the heat dissipation member 4, improve the heat dissipation efficiency of the heat dissipation member 4, and indirectly improve the heat dissipation efficiency of the photosensitive chip 2. The heat dissipation member 4 includes a first layer 45 and a second layer 46. The first layer 45 is a heat-conducting layer, and the second layer 46 is a heat-spreading layer, which can improve the heat conduction efficiency from the photosensitive chip 2 to the metal plate. The extending portion 44 is formed by extending from the second layer 46, and the ductility of the second layer 46 is better than that of the first layer 45, so that the second layer 46 is easier to bend than the first layer 45.

It should be noted that the above embodiments are only used to illustrate the technical solutions of the present disclosure, and not to limit them. Under the idea of the present disclosure, the above embodiments or the technical features in different embodiments can also be combined, and the steps can be implemented in any order. There are many other changes in the different aspects of the present disclosure as described above, which are not provided in detail for the sake of brevity. Although the present disclosure has been described in detail with reference to the above embodiments, those skilled in the art should understand that modifications can still be made to the technical solutions described in the above embodiments, or equivalent replacements can be made for some technical features. These modifications or replacements do not cause the essence of the corresponding technical solutions to depart from the scope of the technical solutions of the embodiments of the present disclosure.

What is claimed is:

1. A packaging structure, comprising:
a circuit board;
a photosensitive chip, electrically connected to the circuit board and comprising a photosensitive surface and a heat dissipation surface opposite the photosensitive surface; and
a heat dissipation member, at least partially in direct contact with the heat dissipation surface of the photosensitive chip.

2. The packaging structure according to claim 1, wherein:
the heat dissipation member is bonded to the circuit board; and
the photosensitive chip is bonded to a side of the heat dissipation member away from the circuit board.

3. The packaging structure according to claim 2, wherein the heat dissipation member is provided with a connecting hole, and the connecting hole is configured for a connecting wire to pass through to electrically connect the photosensitive chip to the circuit board.

4. The packaging structure according to claim 1, wherein:
the circuit board is provided with a through-hole; and
the heat dissipation member is bonded to the circuit board and covers at least a portion of the through-hole, and the photosensitive chip is within the through-hole and bonded to a side of the heat dissipation member facing the circuit board.

5. The packaging structure according to claim 1, wherein:
the circuit board is provided with a through-hole;
the heat dissipation member comprises a sheet portion and a protruding portion, the sheet portion being bonded to the circuit board and covering at least a portion of the through-hole, and the protruding portion being arranged within the through-hole and connected to the sheet portion; and
the photosensitive chip is at least partially bonded to a side of the protruding portion away from the sheet portion.

6. The packaging structure according to claim 5, wherein along a depth direction of the through-hole, the protruding portion matches the through-hole.

7. The packaging structure according to claim 5, wherein along a depth direction of the through-hole, the through-hole matches the photosensitive chip.

8. The packaging structure according to claim 5, wherein along a depth direction of the through-hole, a height of the protruding portion is equal to a depth of the through-hole.

9. The packaging structure according to claim 8, wherein a portion of the photosensitive chip is bonded to the protruding portion, and another portion of the photosensitive chip is bonded to a side of the circuit board away from the sheet portion.

10. The packaging structure according to claim 1, wherein:
the heat dissipation member comprises a sheet portion and an extending portion, the sheet portion being bonded to a surface of the circuit board, and the extending portion extending to another surface of the circuit board.

11. The packaging structure according to claim 10, wherein:
the circuit board comprises a first surface and a second surface that are disposed opposite each other; and
the sheet portion is bonded to one of the first surface and the second surface, and the extending portion extends to the other of the first surface and the second surface.

12. The packaging structure according to claim 1, wherein:
the heat dissipation member comprises a first layer configured to conduct heat of the photosensitive chip, and a second layer configured to conduct heat of the first layer; and
the first layer is bonded to a surface of the circuit board, and the second layer is bonded to a side of the first layer away from the circuit board.

13. The packaging structure according to claim 12, wherein:
the heat dissipation member comprises an extending portion, the extending portion extending from the second layer to another surface of the circuit board; and
a bending performance of the second layer is better than a bending performance of the first layer.

14. The packaging structure according to claim 1, wherein:
the circuit board is provided with a through-hole; and
the photosensitive chip is disposed in the through-hole, and the heat dissipation member is bonded to the heat dissipation surface of the photosensitive chip.

15. The packaging structure according to claim 1, wherein the heat dissipation surface of the photosensitive chip is provided with a thermally conductive adhesive.

16. The packaging structure according to claim 1, wherein:
a side of the heat dissipation member is partially in direct contact with the heat dissipation surface of the photosensitive chip; and
a surface area of another side of the heat dissipation member away from the photosensitive chip is greater than a surface area of the heat dissipation surface of the photosensitive chip.

17. An imaging module, comprising:
a lens holder, provided with a light-passing hole;
a lens, disposed on one end of the lens holder and configured to transmit light into the light-passing hole; and
a packaging structure, comprising:
a circuit board;
a photosensitive chip, electrically connected to the circuit board and comprising a photosensitive surface and a heat dissipation surface opposite the photosensitive surface; and
a heat dissipation member, at least partially in direct contact with the heat dissipation surface of the photosensitive chip,
wherein the packaging structure is disposed on the other end of the lens holder and configured to enable the photosensitive chip to receive light transmitted by the lens.

18. The imaging module according to claim 17, further comprising:
an optical filter at least partially disposed between the lens and the photosensitive chip.

19. The imaging module according to claim 18, wherein the optical filter is configured to cover the packaging structure and enclose the packaging structure to form a sealed cavity, the photosensitive chip being located within the sealed cavity.

20. A camera, comprising:
at least one imaging module, which comprises:
a lens holder, provided with a light-passing hole;
a lens, disposed on one end of the lens holder and configured to transmit light into the light-passing hole; and
a packaging structure, comprising:
a circuit board;
a photosensitive chip, electrically connected to the circuit board and comprising a photosensitive surface and a heat dissipation surface opposite the photosensitive surface; and
a heat dissipation member, at least partially in direct contact with the heat dissipation surface of the photosensitive chip,
wherein the packaging structure is disposed on another end of the lens holder and configured to enable the photosensitive chip to receive light transmitted by the lens.
